(19) United States
(12) Patent Application Publication
(10) Pub. No.: US 2026/0118897 A1
(43) Pub. Date: Apr. 30, 2026

(54) VOLTAGE CONTROL CIRCUIT AND VOLTAGE SUPPLY SYSTEM INCLUDING THE SAME

(71) Applicant: Samsung Electronics Co., Ltd., Suwon-si (KR)

(72) Inventor: Jeil Ryu, Suwon-si (KR)

(21) Appl. No.: 19/322,971

(22) Filed: Sep. 9, 2025

(30) Foreign Application Priority Data
Oct. 24, 2024 (KR) 10-2024-0146549

(51) Int. Cl. G05F 1/59; H03F 3/45

(52) U.S. Cl. CPC G05F 1/59; H03F 3/45475

(57) ABSTRACT

A voltage control circuit includes an operational transconductance amplifier circuit including a floating current source that is configured to receive a power voltage and is further configured to output a first current and a second current based on a difference between input voltage signals, a voltage conversion circuit including a first transistor that is configured to receive the first current and a second transistor that is configured to receive an input voltage, the second transistor being further configured to output a first voltage based on the first transistor being electrically connected to the power voltage, and a voltage output circuit including a third transistor electrically connected to the second transistor by a common input node and a fourth transistor configured to receive the second current, in which the common input node is configured to receive the first output voltage and the third transistor is configured to receive the input voltage.

### CROSS-REFERENCE TO RELATED APPLICATION

This application claims the benefit of Korean Patent Application No. 10-2024-0146549, filed on October 24, 2024, in the Korean Intellectual Property Office, the disclosure of which is incorporated herein by reference in its entirety.

### BACKGROUND

### 1. Field of the Invention

The present disclosure relates to a voltage control circuit and a voltage supply system including the same.

### 2. Description of the Related Art

In a memory device, a voltage control circuit is a core element for maintaining a stable output voltage. A class A amplifier may be used as an output stage of the voltage control circuit. The class A amplifier may be designed to be simple and have high linearity. However, power consumption may be high because the class A amplifier consumes power even without an input signal, and an output voltage may not be rapidly pulled down from a high voltage to a low voltage.

A class AB output stage provides a high current driving capability by combining advantages of a class A and a class B. In addition, the class AB output stage may provide less heat generation and high output power. Also, the class AB output stage has less distortion by maintaining a characteristic of the class A for a small signal and has higher efficiency by operating as the class B as a signal becomes larger. The class AB output stage may be used to rapidly process voltage transition from the high voltage (HV) to the low voltage (LV).

The class AB output stage may implement rapid voltage pull down for heterogeneous input voltages even in a large-capacity capacitor load. However, for the heterogeneous voltages, a class AB scheme may cause excessive use of a high-voltage current. The excessive use of the HV current may increase power consumption of a HV pump, which decreases power efficiency of a system.

Due to an increase in the power consumption of the HV pump, power consumption of the entire system is increased, and heat emission is increased. Accordingly, stability and reliability of the system may be decreased. In addition, an excessive HV current may increase stress on a circuit element and shorten a life thereof.

### SUMMARY

An aspect of the inventive concept provides a voltage supply system and a voltage control circuit included in the voltage supply system.

However, the goals to be achieved by example embodiments of the present disclosure are not limited to the objectives described above and other objects may be clearly understood from the following example embodiments.

According to an embodiment of the disclosure, there is provided a voltage control circuit including an operational transconductance amplifier (OTA) circuit including a floating current source that is configured to receive a power voltage and is further configured to output a first current and a second current based on a difference between input voltage signals, a voltage conversion circuit including a first transistor that is configured to receive the first current and a second transistor that is configured to receive an input voltage, the second transistor being further configured to output a first voltage based on the first transistor being electrically connected to the power voltage, and a voltage output circuit including a third transistor electrically connected to the second transistor by a common input node and a fourth transistor configured to receive the second current, wherein the third transistor and fourth transistor are, in combination, configured to output a final output voltage based on receipt of the first output voltage at the common input node and receipt of the input voltage at the third transistor.

According to another aspect, there is also provided a voltage supply system including a regulator, a voltage control circuit configured to receive a regulator voltage from the regulator, and a generator configured to generate a generator voltage based on a final output voltage generated by the voltage control circuit, and the voltage control circuit includes an operational transconductance amplifier (OTA) circuit including a floating current source that is configured to receive a power voltage and is configured to output a first current and a second current based on a difference between input voltage signals, a voltage conversion circuit including a first transistor configured to receive the first current and a second transistor configured to receive an input voltage, the second transistor being configured to output a first output voltage based on the first transistor being electrically connected to the power voltage, and a voltage output circuit including a third transistor electrically connected to the second transistor by a common input node and a fourth transistor configured to receive the second current, wherein the third transistor and the fourth transistor are, in combination, configured to output the final output voltage based on receipt of the first output voltage at the common input node and receipt of the input voltage at the third transistor.

Additional aspects of example embodiments will be set forth in part in the description which follows and, in part, will be apparent from the description, or may be learned by practice of the disclosure.

According to example embodiments, it may be possible to provide a voltage control circuit that decreases a high-voltage current and a memory device including the same. As a floating current source is included in an operation transconductance amplifier (OTA), high-voltage pump power may be decreased by reducing a path of a high-voltage current.

According to example embodiments, as the path of the high-voltage current is reduced, it may be possible to reduce the number of elements used in the voltage control circuit and drive the voltage control circuit in a smaller area.

Effects of embodiments of the present disclosure are not limited to those described above and other effects of embodiments of the present disclosure may be made apparent to those skilled in the art from the following description and the accompanying claims.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a block diagram illustrating a voltage supply system including a voltage control circuit according to an example embodiment;

FIG. 2 is a diagram illustrating a voltage control circuit including a class A and an operational transconductance amplifier (OTA) circuit according to an example embodiment;

FIG. 3 is a diagram illustrating a voltage control circuit including a class AB output stage and an operational transconductance amplifier (OTA) circuit according to an example embodiment;

FIG. 4 is a graph illustrating output voltage changes depending on input voltage changes in a voltage control circuit including a class A and a voltage control circuit including a class AB output stage according to an example embodiment;

FIG. 5 is a block diagram illustrating an element of a voltage control circuit according to an example embodiment;

FIG. 6 illustrates a voltage control circuit having heterogeneous input voltages according to an example embodiment;

FIG. 7 illustrates a voltage control circuit including a class AB output stage having heterogeneous input voltages and a symmetrical complementary metal-oxide-semiconductor (CMOS) operational transconductance amplifier (OTA); and

FIG. 8 illustrates a voltage control circuit including a class AB output stage having heterogeneous input voltages and a symmetrical complementary metal-oxide-semiconductor (CMOS) operational transconductance amplifier (OTA) of a resistive common mode feedback circuit.

### DETAILED DESCRIPTION

Terms used in the example embodiments are selected, as much as possible, from general terms that are widely used at present while taking into consideration the functions obtained in accordance with the present disclosure, but these terms may be replaced by other terms based on intentions of those skilled in the art, customs, emergence of new technologies, or the like. Also, in a particular case, terms that are arbitrarily selected by the applicant of the present disclosure may be used. In this case, the meanings of these terms may be described in corresponding description parts of the disclosure. Accordingly, it should be noted that the terms used herein should be construed based on practical meanings thereof and the whole content of this specification, rather than being simply construed based on names of the terms. As used herein, the term "and/or" includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

In the entire specification, when an element is referred to as "including" another element, the element should not be understood as excluding other elements so long as there is no special conflicting description, and the element may include at least one other element. In addition, the terms "unit" and "module", for example, may refer to a component that exerts at least one function or operation, and may be realized in hardware or software, or may be realized by combination of hardware and software.

Throughout the specification, expression "at least one of a, b, and c" may include 'a only', 'b only', 'c only', 'a and b', 'a and c', 'b and c', or 'all of a, b, and c'.

In the present disclosure, a "terminal" may be implemented as a computer or a portable terminal capable of accessing a server or another apparatus through a network. The computer may include, for example, a laptop computer, a desktop computer, and a notebook equipped with a web browser. The portable apparatus may be a wireless communication device ensuring a portability and a mobility, and include any type of handheld wireless communication device, for example, a tablet PC, a smartphone, a communication-based apparatus such as international mobile telecommunication (IMT), code division multiple access (CDMA), W-code division multiple access (W-CDMA), and long term evolution (LTE).

In the following description, example embodiments of the present disclosure will be described in detail with reference to the accompanying drawings so that those skilled in the art can easily carry out the present disclosure. However, the present disclosure may be embodied in many different forms and is not limited to the example embodiments described herein.

In describing the example embodiments, descriptions of technical contents that are well known in the art to which the present disclosure belongs and are not directly related to the present specification will be omitted. This is to more clearly communicate without obscuring the subject matter of the present specification by omitting unnecessary description.

For the same reason, in the accompanying drawings, some components are exaggerated, omitted or schematically illustrated. In addition, the size of each component does not fully reflect the actual size. The same or corresponding components in each drawing are given the same reference numerals.

Advantages and features of the present disclosure and methods of achieving them will be apparent from the following example embodiments that will be described in more detail with reference to the accompanying drawings. It should be noted, however, that the present disclosure is not limited to the following example embodiments, and may be implemented in various forms. Accordingly, the example embodiments are provided only to disclose the present disclosure and let those skilled in the art know the category of the present disclosure, and the present disclosure is merely defined by the category of the claims. The same reference numerals or the same reference designators denote the same elements throughout the specification.

At this point, it will be understood that each block of the flowchart illustrations and combinations of flowchart illustrations may be performed by computer program instructions. These computer program instructions may be embodied in a processor of a general purpose computer, a special purpose computer, or other programmable data processing equipment such that the instructions performed by the processor of the computer or other programmable data processing equipment generate parts for performing functions described in flowchart block(s). These computer program instructions may use a computer or other programmable data processing equipment for implementing a function in a specific manner or may be stored in a computer readable memory, and thus the instructions which use the computer or are stored in the computer readable memory may produce a manufacturing article including instruction parts for performing the functions described in the flowchart block(s). Since the computer program instructions can also be embedded in the computer or other programmable data processing equipment, instructions, which a series of operations are performed on the computer or other programmable data processing equipment to generate a computer-executed process, thereby operating the computer or other programmable data processing equipment, can provide operations for performing the functions described in the flowchart block(s).

In addition, each block may represent a module, segment, or a portion of code, which includes one or more executable instructions for executing specified logical function(s). It should also be noted that, in some alternative example embodiments, it is also possible for the functions mentioned in the blocks to occur out of the order. For example, two blocks shown in succession may, in fact, be executed substantially concurrently, or the blocks may sometimes be executed in the reverse order, depending upon the functionality involved.

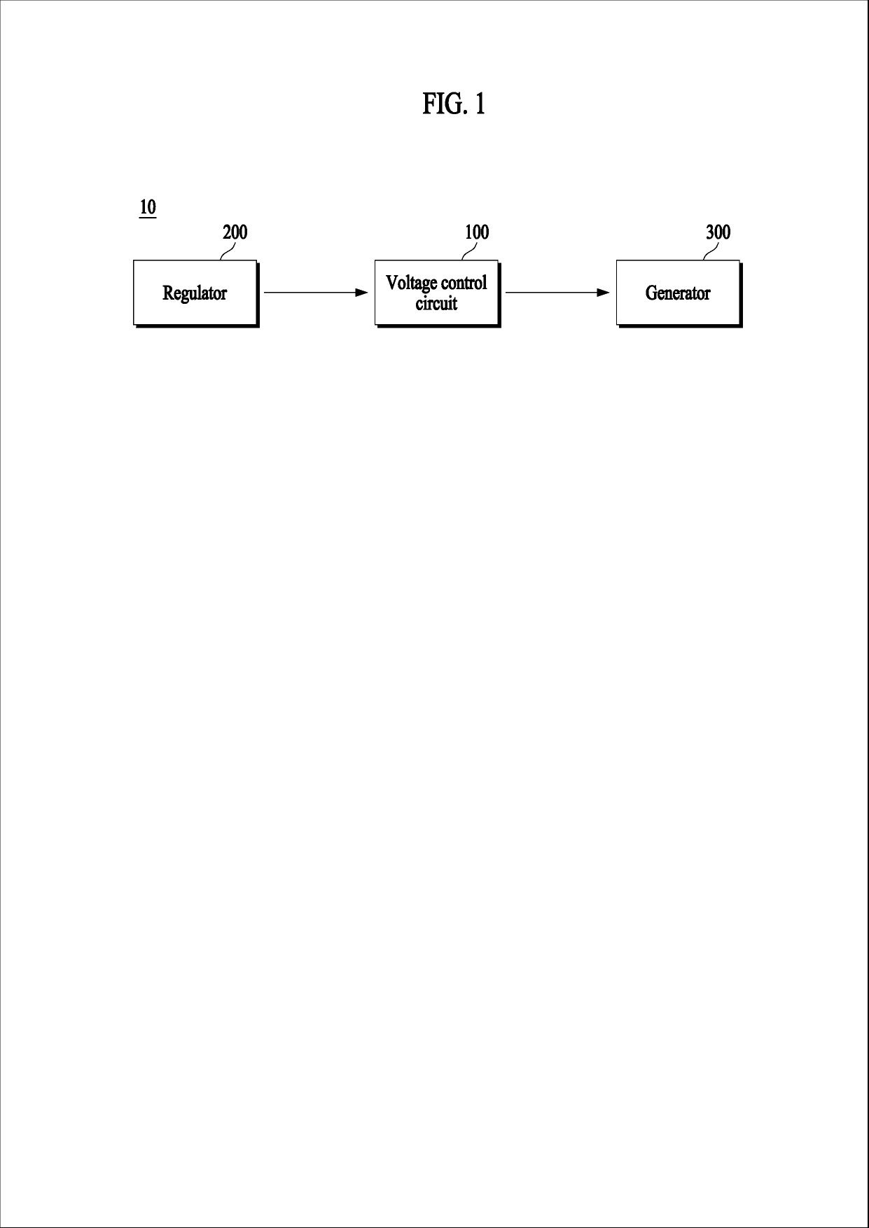

FIG. 1 is a block diagram illustrating a voltage supply system including a voltage control circuit according to an example embodiment.

Referring to FIG. 1, a voltage supply system 10 according to an example embodiment may control and supply an operation voltage for an operation of an electronic device. In an example embodiment, the electronic device may be a memory device, but it is merely an example. The electronic device may be various types of devices such as a smartphone, a tablet, a computer, a mobility device (e.g., a car, a drone, a ship, an air plane, or the like), an industrial equipment (e.g., a robot, a semiconductor process equipment, or the like), a wearable device (e.g., a smart watch, a smart ring, smart glasses, or the like), a camera, a communication device (e.g., a router, a relay, or the like), a home appliance (e.g., a washing machine, a refrigerator, or the like), a medical device (e.g., a magnetic resonance imager, a sonograph, an X-ray examination device, or the like), and a display (e.g., a television, a monitor, or the like).

In an example embodiment, the voltage supply system 10 may be disposed in the electronic device. In other words, the voltage supply system 10 may be included in the electronic device. In this case, the voltage supply system 10 may be connected to another element included in the electronic device through a bus.

In an example embodiment, the voltage supply system 10 may be disposed outside or external to the electronic device. In this case, the voltage supply system 10 may be connected to the electronic device through a power connector.

In an example embodiment, the voltage supply system 10 may include a regulator 200, a voltage control circuit 100, and a generator 300. For convenience for description, the voltage control circuit 100 is illustrated as being distinguished from the generator 300, but the voltage control circuit 100 may be disposed in the generator 300. That is, the voltage control circuit 100 may be included in the generator 300.

The regulator 200 may stabilize and adjust power supplied from an external power source. The regulator 200 may maintain a voltage to be applied to the voltage control circuit 100 at a suitable or desirable level by precisely adjusting an input voltage. In an example embodiment, the regulator 200 may apply a first voltage and a second voltage different from each other to the voltage control circuit 100. The regulator 200 may adjust the input voltage which is input to the voltage control circuit 100 and perform a filtering or limitation function for setting a voltage according to a condition designed in advance. In performing the filtering or limitation function, the regulator 200 may remove noise in an input signal or remove a voltage spike.

In an example embodiment, the voltage control circuit 100 may receive one or more voltages from the regulator 200 and perform a rapid voltage change at an output node of the voltage control circuit 100 in a situation in which an output voltage of the regulator 200 is to be rapidly decreased. The voltage control circuit 100 may include a class AB output stage for rapid voltage conversion.

The class AB output stage provides a high current driving capability by combining advantages of a class A and a class B. In addition, the class AB output stage may provide less heat generation and high output power. Also, the class AB output stage has less distortion by maintaining a characteristic of the class A for a small signal and has higher efficiency by operating as the class B as a signal becomes larger. Thus, the voltage control circuit 100 may include the class AB output stage to rapidly process voltage transition from a high voltage HV to a low voltage LV.

In an example embodiment, two different voltages may be applied to the voltage control circuit 100. When the voltage control circuit 100 which receives the two different voltages uses the class AB output stage, a large number of paths for a high-voltage current may be present. When the large number of paths for the high voltage current are present, an increase in high-voltage pump power may result. Through this, excessive power consumption may occur. In an example embodiment of the present disclosure, when receiving two different heterogeneous voltages, the voltage control circuit 100 may include a float current source in an operation transconductance amplifier (OTA) included in the voltage control circuit 100. As the floating current source is included in the OTA, the voltage control circuit 100 may reduce a path connected from a higher voltage among the heterogeneous voltages to a ground.

Here, the floating current source may represent a current source that may independently operate between two points without being connected to the ground or a fixed voltage reference point. The floating current source may be used to supply or maintain a constant current between the two points or nodes of a circuit. In an example embodiment, the floating current source may be a Monticelli cell. The Monticelli cell is a type of the floating current source. The Monticelli cell may be used in a current mirror circuit, may have a structure efficient at generating and duplicating a current, and may be designed to be physically or electrically isolated from a peripheral circuit.

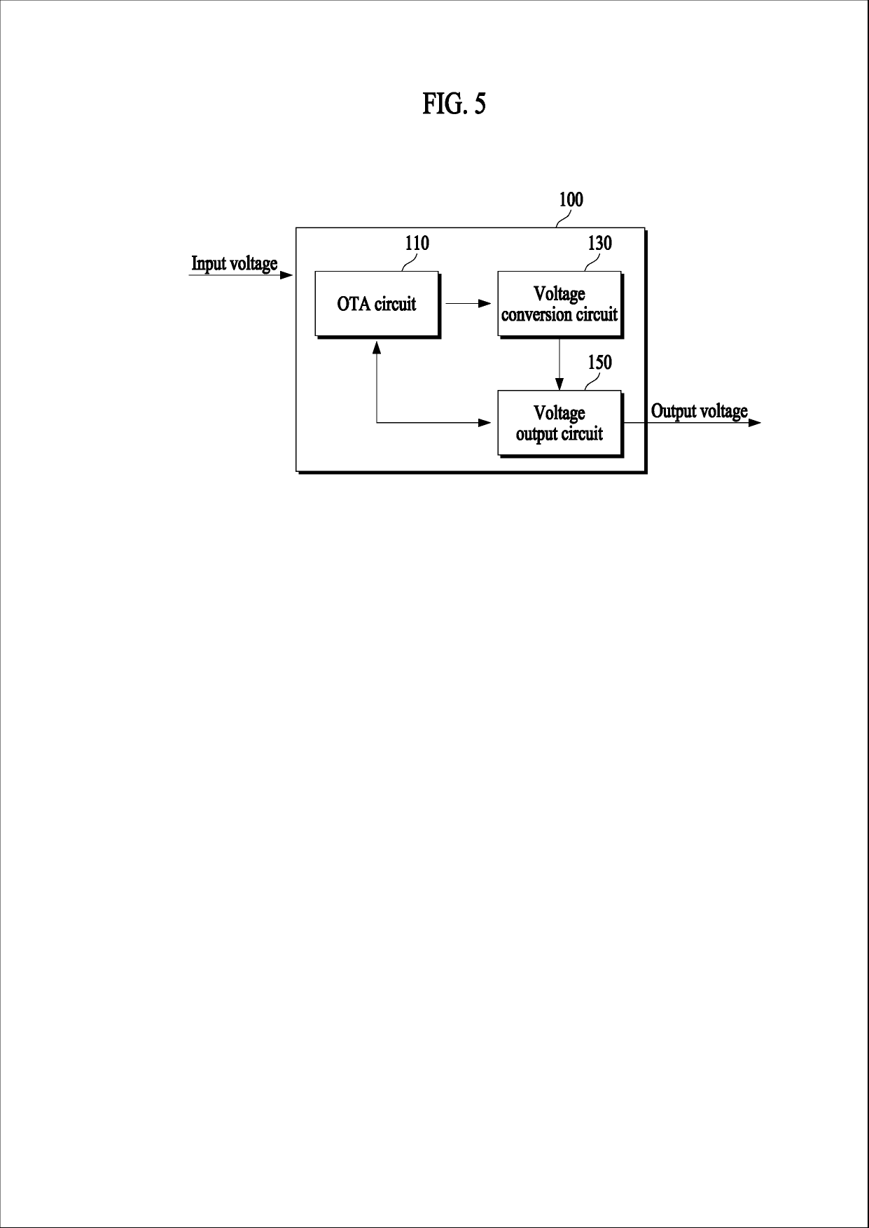

A detailed example and a voltage control operation of the voltage control circuit 100 according to an example embodiment will be described in detail below with reference to FIGS. 5 through 8.

The generator 300 may receive a controlled voltage from the voltage control circuit 100 to stably supply a voltage to a word line of the memory device.

Here, the word line may be a line connected along a row of a memory cell in a semiconductor memory chip included in a semiconductor storage device such as a NOT-AND (NAND) flash memory or a dynamic random access memory. A memory storage device may select and activate memory cells in a predetermined row through the word line and may read or write data therethrough. A voltage required for the memory cell may be supplied through the word line, and the word line may set a data bit by applying the voltage to the cell.

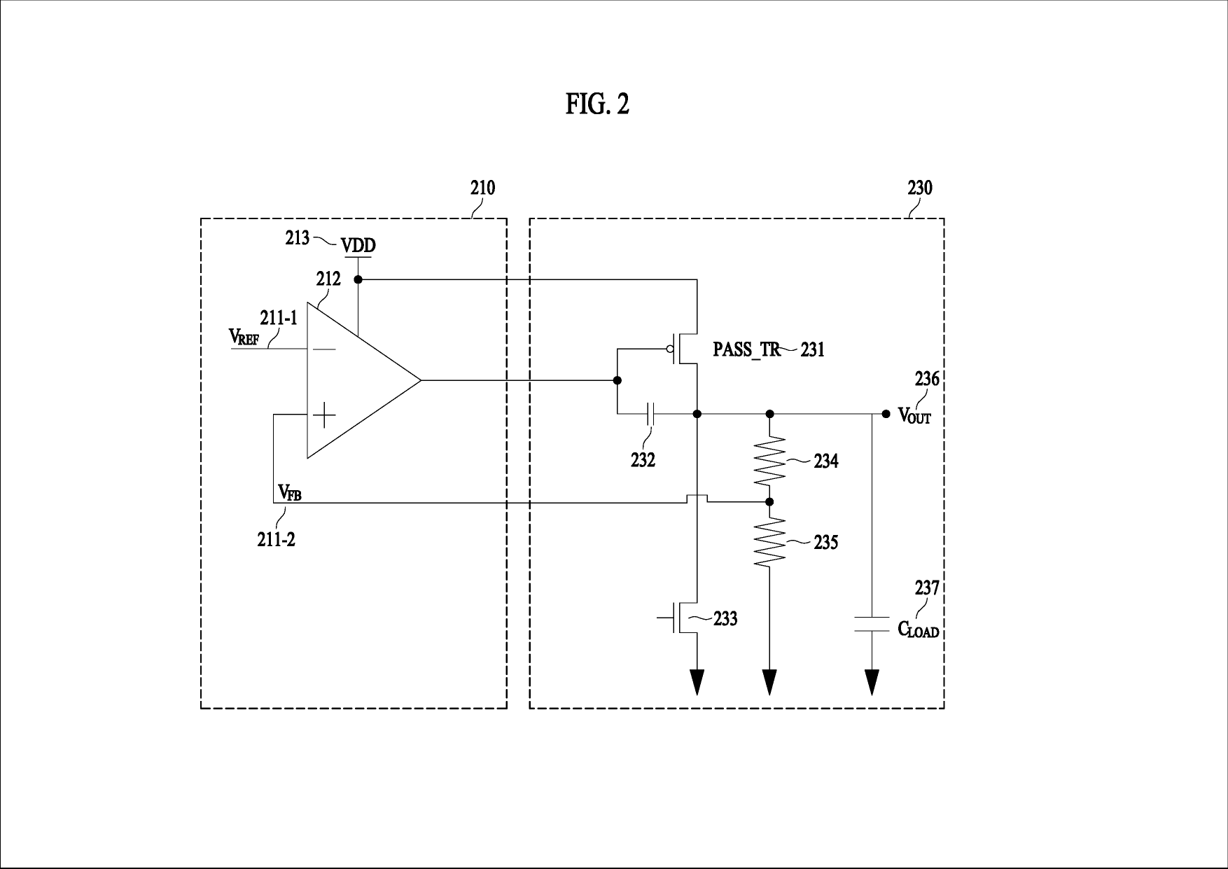

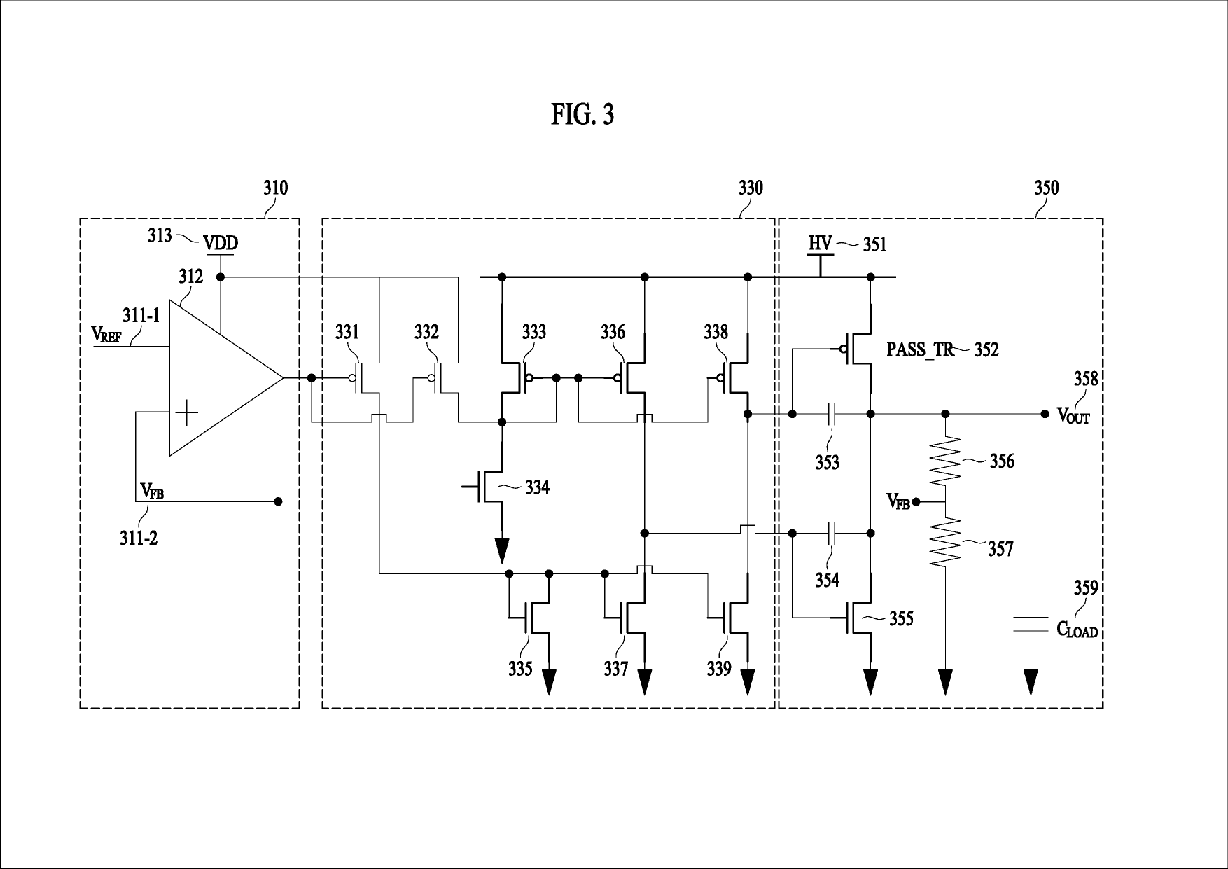

Hereinafter, a circuit including a class A output stage and the class AB output stage will be described with reference to FIGS. 2 and 3, which include a detailed example.

FIG. 2 is a diagram illustrating a voltage control circuit including a class A and an operational transconductance amplifier (OTA) circuit.

Referring to FIG. 2, the voltage control circuit 100 may receive an input of V_{DD} 213 that is one input voltage to output Vₒᵤₜ 236 that is an output voltage. The voltage control circuit 100 may include an OTA circuit 210 and a voltage output circuit 230. Here, the voltage output circuit 230 may include a class A output stage.

The OTA circuit 210 may apply an adjusted voltage to the voltage output circuit 230 with V_{REF} 211-1 as a reference voltage. The V_{REF} 211-1 may be a voltage connected to a positive input of an operational amplifier 212, and the voltage may be supplied from an external power supply device. A portion of an output voltage of the operational amplifier 212 may be sampled, so that V_{FB} 211-2, which is a feedback voltage, may be connected to a negative input of the operational amplifier 212. The V_{FB} 211-2 may serve to compare a degree to which the output voltage of the operational amplifier 212 and the V_{REF} 211-1 match. The operational amplifier 212 may amplify a voltage difference between the V_{REF} 211-1 and the V_{FB} 211-2 and control a gate of a pass transistor 231, which is a p-channel metal-oxide-semiconductor (PMOS) transistor included in the voltage output circuit 230. Here, the operational amplifier 212 may correspond to an OTA and use the V_{DD} 213 which is a positive-side power source terminal voltage used to drive the operational amplifier 212. The V_{DD} 213 may be supplied from the regulator 200 of FIG. 1 and may be a voltage supplied for driving the pass transistor 231.

The voltage output circuit 230 may include the class A output stage and may be electrically connected to the OTA circuit 210 to control a value of the Vₒᵤₜ 236 which is a final output voltage.

The voltage output circuit 230 may include the pass transistor 231, a first capacitor 232, a first transistor 233, a first resistor 234, a second resistor 235, and C_{LOAD} 237, which is a load capacitor.

The pass transistor 231 may serve to transfer the input voltage to an output. Specifically, according to an operation of the pass transistor 231, the input voltage may be adjusted to be transferred as an output voltage. The pass transistor 231 may be designed so that a loss of voltage is reduced or minimized in a process of transferring. The pass transistor 231 may transfer all entire input voltages as a load in an "ON" state.

The first capacitor 232 may be electrically connected to the pass transistor 231, the operational amplifier 212, and the first transistor 233 to serve to filter a voltage change that may occur at the output and remove or reduce noise due to a rapidly changing signal.

The first transistor 233 may operate together with the pass transistor 231 to increase stability and precision of the Vₒᵤₜ 236 and may additionally control a current flow toward the C_{LOAD} 237.

The first resistor 234 and the second resistor 235 may be disposed on a feedback path of the operational amplifier 212 to determine a voltage of the V_{FB} 211-2 by distributing the voltage. The first resistor 234 and the second resistor 235 may sense a change in the output voltage of the operational amplifier 212 and transfer the distributed voltage as the V_{FB} 211-2 which is the feedback voltage to the operational amplifier 212.

The C_{LOAD} 237, which is the load capacitor, may be electrically connected to the Vₒᵤₜ 236 to serve to maintain overall stability of the circuit and minimize or reduce the voltage change.

In a voltage push-up situation, the voltage control circuit 100, which includes the class A output stage, may pass a higher voltage from the V_{DD} 213 to the Vₒᵤₜ 236 by greatly opening the pass transistor 231 further, so that the Vₒᵤₜ 236 may be rapidly pushed up. However, in a voltage pull-down situation, when the operational amplifier 212 determines that the V_{FB} 211-2 is greater than the V_{REF} 211-1, a control signal for decreasing an output of the operational amplifier 212 may be generated. In addition, the generated control signal may turn off the pass transistor 231. However, since the pass transistor 231 is not completely turned off, and since a predetermined amount of a current may flow, the Vₒᵤₜ 236 may be slowly pulled down.

In other words, the voltage control circuit 100 including the class A output stage may not be suitable for performing rapid voltage pull-down conversion for the regulator 200.

In an example embodiment, for the rapid voltage pull-down conversion for the regulator 200, the voltage control circuit 100 may use a circuit including a class AB output stage which combines advantages of the class A and a class B. Also, in a heterogeneous input voltage supply situation in which a high voltage provision source is provided together with the V_{DD} 213 which is a low voltage provision source, the voltage control circuit 100 may include the class AB output stage.

FIG. 3 is a diagram illustrating a voltage control circuit including a class AB output stage and an operational transconductance amplifier (OTA) circuit.

Referring to FIG. 3, in an example embodiment, the voltage control circuit 100 may include an OTA circuit 310, a voltage conversion circuit 330, and a voltage output circuit 350. The OTA circuit 310 may be a circuit including a operational amplifier 312. The voltage conversion circuit 330 may be a circuit taking an output of the operational amplifier 312 as a gate input to a first transistor 331 and a second transistor 332 and serving to amplify and control a voltage of V_{DD} 313, which is a low-voltage input voltage. The voltage output circuit 350 may include the class AB output stage. Due to the class AB output stage, an operation in which Vₒᵤₜ 358, which is a final output voltage, rapidly decreases a voltage in response to a voltage being rapidly pulled down may be performed.

The OTA circuit 310 may include the operational amplifier 312. The operational amplifier 312 may correspond to an OTA. The operational amplifier 312 may generate a control signal by amplifying a voltage difference between V_{REF} 311-1 that is a reference voltage and V_{FB} 311-2 that is a feedback voltage. The generated control signal may be used to adjust the Vₒᵤₜ 358. The V_{DD}313 may be supplied from the regulator 200 of FIG. 1 and may not be supplied for driving a pass transistor 352 unlike a class A output stage.

The voltage conversion circuit 330 may serve to convert HV 351, which is a high-voltage power source, into the Vₒᵤₜ 358 by using a plurality of transistors. A push-pull operation of a transistor may be performed in a voltage conversion process.

A first transistor 331 and a second transistor 332 may adjust the voltage of the V_{DD} 313 according to an output current of the operational amplifier 312 to be electrically connected to gates of a third transistor 333, a fifth transistor 335, a sixth transistor 336, a seventh transistor 337, an eighth transistor 338, and a ninth transistor 339 and control an operation of each transistor. The fifth transistor 335 may form a low-voltage current path that is electrically connected to the first transistor 331 and a ground from the V_{DD} 313.

The third transistor 333 and a fourth transistor 334 may be electrically connected to the HV 351 and the ground to form a first path. The sixth transistor 336 and the seventh transistor 337 may be electrically connected to the HV 351 and the ground to form a second path. The eighth transistor 338 and the ninth transistor 339 may be electrically to the HV 351 and the ground to form a third path. Here, since being a path in which a relatively higher current flows from the high-voltage HV 351 to the ground when compared with the low-voltage current path, the first path, the second path, and the third path correspond to a portion at which overall power consumption is relatively larger.

The voltage output circuit 350 may include the HV 351, which is the high-voltage power source, the pass transistor 352, a tenth transistor 355, a first capacitor 353, a second capacitor 354, a first resistor 356, a second resistor 357, and a load capacitor 359.

The HV 351 may be the high-voltage power source and a power source supplied from the regulator 200. In an example embodiment, the HV 351 may have a voltage value greater than that of the V_{DD}313. For example, the V_{DD} 313 may have a value between 1.5 volts (V) and 2.5 V, and the HV 351 may have a value greater than or equal to 10 V. In addition, a maximum value of the V_{DD} 313 and a minimum value of the HV 351 may differ by 4.7 times or more.

As such, the voltage control circuit 100 may be supplied with heterogeneous voltages to rapidly and efficiently cope with a change in a voltage by switching a high voltage to a low voltage or the low voltage to the high voltage.

The pass transistor 352 may serve to adjust the Vₒᵤₜ 358 which is the final output voltage by adjusting a high voltage supplied from the HV 351. The tenth transistor 355 may be electrically connected to the pass transistor 352 to form a current path from the HV 351 to the ground according to control by the sixth transistor 336.

The first capacitor 353 and the second capacitor 354 may be electrically connected respectively between a gate of the pass transistor 352 and a drain of the pass transistor 352 and between a gate of the tenth transistor 355 and a source of the tenth transistor 355 to suppress occurrence of a ripple. Through this, the first capacitor 353 and the second capacitor 354 may serve to provide a more stable output.

The first resistor 356 and the second resistor 357 may be electrically connected to the Vₒᵤₜ 358 and the V_{FB} 311-2 which is the feedback voltage of the operational amplifier 312 to control an operation of the operational amplifier 312 according to distribution of the voltage of the Vₒᵤₜ 358.

C_{LOAD} 359, which is the load capacitor, may be electrically connected to the Vₒᵤₜ 358 to serve to maintain overall stability of the circuit and minimize or reduce a voltage change.

Since two types of transistors therein alternately operate to process a voltage being pushed up and pulled down, the voltage control circuit 100, which includes the class AB output stage, may rapidly decrease the voltage in a pull-down situation.

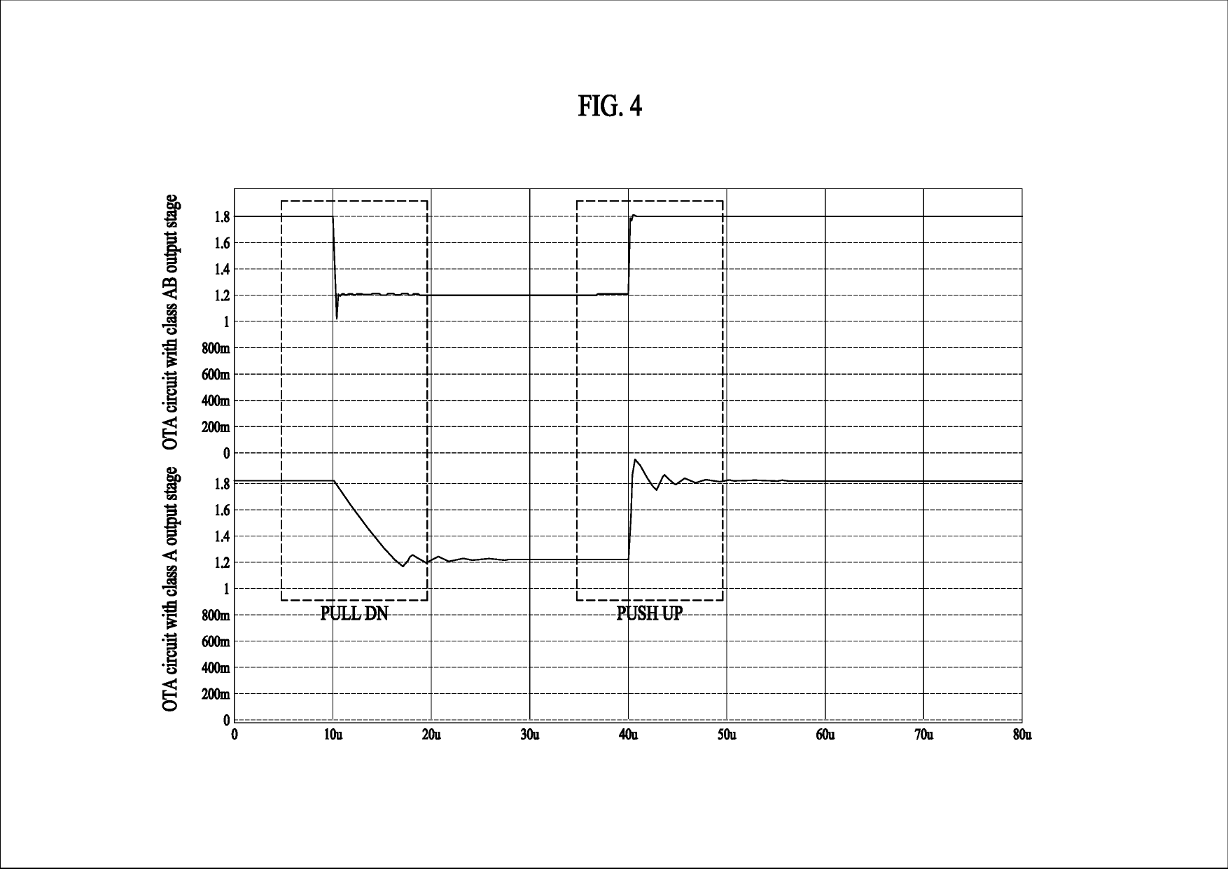

FIG. 4 is a graph illustrating output voltage changes depending on input voltage changes in a voltage control circuit including a class A output stage and a voltage control circuit including a class AB output stage.

Referring to FIG. 4, an x-axis of the graph represents a time (seconds), and a y-axis thereof represents an output voltage (V).

In the graph, in an OTA circuit with the class A output stage such as that of FIG. 2, it may be identified that a voltage is rapidly pushed up in a push-up situation 430 at 40u seconds and that in a pull-down situation 410 at 10u seconds, approximately 10u seconds are consumed until the voltage is gradually decreased to be stable.

In an OTA circuit with the class AB output stage in combination of characteristics of the class A output stage and a class B output stage, such as that of FIG. 3, it may be identified that a voltage is rapidly pushed up in the push-up situation 430 at the 40u seconds time point and that the voltage is rapidly pulled down even in the pull-down situation 410 at the 10u seconds time point.

In addition, when compared with the OTA circuit with the class A output stage, the OTA circuit with the class AB output stage according to an example embodiment may be identified as consuming a less time until the voltage becomes stable in a situation in which the voltage is rapidly changed such as the pull-down situation 410 and the push-up situation 430.

That is, in the pull-down 410 situation and the push-up situation 430, the voltage may be rapidly pulled down and pushed up and also may be further rapidly stabilized in a case of using the class AB output stage when compared with a case of using the class A output stage. Thus, in a pull-down situation and a push-up situation in which the voltage is to be rapidly increased and decreased through a word line, such as a NOT-AND (NAND) flash memory, the voltage control circuit including the class AB output stage may be effective in various actions including rapid memory reading and writing.

Referring back to FIG. 3, when heterogeneous voltages are taken as an input, excessive power consumption may occur due to a high-voltage current path including the first path, the second path, and the third path from the HV 351 toward a ground, which are described above.

In addition, a cost of transistors included in the above-described three paths may be inappropriate, and a space included in a memory device may be wasted due to the transistors. Thus, when the heterogeneous voltages are used, a method of reducing the high-voltage current path while using the class AB output stage may be desired.

Hereinafter, according to an example embodiment, a circuit element for reducing the high-voltage current path through an OTA circuit including a floating current source and a detailed example thereof will be described with respect to FIGS. 5 through 8.

FIG. 5 is a block diagram illustrating an element of a voltage control circuit according to an example embodiment.

Referring to FIG. 5, the voltage control circuit 100 according to an example embodiment may output an output voltage as a final output voltage by receiving, as an input voltage, an input of a first input voltage and a second input voltage that are heterogeneous.

In an example embodiment, the voltage control circuit 100 may include an OTA circuit 110, a voltage conversion circuit 130, and a voltage output circuit 150. In the present disclosure, for convenience for description, the voltage control circuit 100 is described as including the OTA circuit 110, the voltage conversion circuit 130, and the voltage output circuit 150. However, it is merely an example. The voltage control circuit 100 may further include a circuit and an element for an additional function.

In an example embodiment, a first voltage may be a power voltage for driving an OTA, and a second voltage may be an input voltage for generating an output voltage. The second voltage may have a voltage value greater than that of the first voltage.

In addition, in an example embodiment, the first voltage may have a value between 1.5 V and 2.5 V, and the second voltage may have a value greater than or equal to 10 V. For example, a maximum value of the first voltage and a minimum value of the second voltage may differ by 4.7 times or more.

In an example embodiment, the OTA circuit 110 may be a type of an amplifier that receives a voltage as an input and sends a current as an output. An output current in proportion to an input voltage may be generated based on a parameter of transconductance.

In an example embodiment, the OTA circuit 110 may include a floating current source. The floating current source may represent a current source that may independently operate between two points without being connected to a ground or a fixed voltage reference point. The floating current source may be used to supply or maintain a constant voltage between two points of a circuit. In an example embodiment, the floating current source may be a Monticelli cell. The Monticelli cell is a type of floating current source. The Monticelli cell may be used in a current mirror circuit, may have a structure efficient at generating and duplicating a current, and may be designed to be physically or electrically isolated from a peripheral circuit.

In an example embodiment, the floating current source may include an n-channel metal-oxide-semiconductor (NMOS) transistor and a p-channel metal-oxide-semiconductor (PMOS) transistor of which sources and drains are symmetrically connected. The floating current source may perform control so that a bias voltage is applied to a gate of each of the NMOS transistor and the PMOS transistor, a first current is output from a source of the NMOS transistor, and a second current is output from a source of the PMOS transistor based on a difference between input voltage signals.

Since the OTA circuit 110 according to an example embodiment is not to control all transistors with a high voltage because the OTA circuit 110 includes the floating current source, which is the current source that may independently operate between the two points or nodes, a current path from a high voltage among heterogeneous voltages toward the ground may be reduced.

Also, the OTA circuit 110 including the floating current source may control, with a low voltage among the heterogeneous voltages, a pull-down transistor included in the voltage output circuit 150, which includes a class AB output stage.

In an example embodiment, an NMOS transistor or a PMOS transistor may be used at an input node of the OTA circuit 110, so that the OTA circuit 110 may serve to convert an input signal into the current. Further specifically, the OTA circuit 110 may include an input NMOS transistor or an input PMOS transistor, and the input signal may be input to a gate of the input NMOS transistor or the input PMOS transistor.

When the input node of the OTA circuit 110 is the NMOS transistor, good performance may be shown in a condition of a low power source voltage or a low-voltage signal. When the input node of the OTA circuit 110 is the PMOS transistor, the input node of the OTA circuit 110 may further more stably operate in a high-voltage condition, and since a higher voltage may be applied to the gate, an input operation range may be extended.

In an example embodiment, the OTA circuit 110 may be a circuit to which a rail-to-rail folded cascode structure is applied.

In an example embodiment, in the rail-to-rail folded cascode structure, a drain of an NMOS transistor may be electrically connected to a source of a cascode PMOS transistor, a drain of a PMOS transistor may be electrically connected to a drain of a cascode NMOS transistor, a source of the cascode NMOS transistor may be electrically connected to the ground, the source of the cascode PMOS transistor may be electrically connected to a power source voltage.

A rail-to-rail operation may be a capability of an amplifier to swing an output voltage so that the output voltage is close to a rail that is a range of a voltage of power supply. In other words, the circuit may have a wide output range for correspondingly reaching a maximum value and a minimum value of the power source voltage. When the rail-to-rail operation is allowed, since input and output signals may be used up to both extremes of the power source voltage, efficiency may be high, and the entire power source voltage may be effectively used.

A folded cascode may represent a circuit structure for improving performance of the amplifier by connecting transistors in a predetermined scheme. A cascode structure may improve overall performance of the amplifier by increasing a voltage benefit of the input signal and increasing an output impedance. "Folded" may represent that a cascode circuit is changed so that an input transistor is designed to effectively operate at a voltage lower than that of a general cascode structure.

In other words, when being the circuit to which the folded cascode structure for the rail-to-rail operation is applied, the OTA circuit 110 may represent a circuit of which an amplifier provides a high voltage benefit by using an entire range of the power source voltage and that is designed to effectively operate even in a broadband bandwidth.

In an example embodiment, the OTA circuit 110 may be a symmetrical complementary metal-oxide-semiconductor (CMOS) OTA circuit or a symmetrical CMOS OTA circuit including a resistive common feedback circuit.

For example, the OTA circuit 110 may include a differential pair of NMOS transistors or PMOS transistors and a current mirror circuit, and the OTA circuit 110 may include a symmetrical CMOS OTA circuit in which the input signal is applied to each gate of the differential pair, sources of the differential pair are electrically connected and supplied with a constant bias current, and drains of the differential pair are electrically connected to the current mirror circuit.

Also, the OTA circuit 110 may further include a first resistor, a second resistor, and a symmetrically structured cascode transistor, and the OTA circuit 110 may further include the resistive common feedback circuit in which each of the first resistor and the second resistor is electrically connected between a gate and a drain of the cascode transistor to sense a common mode voltage.

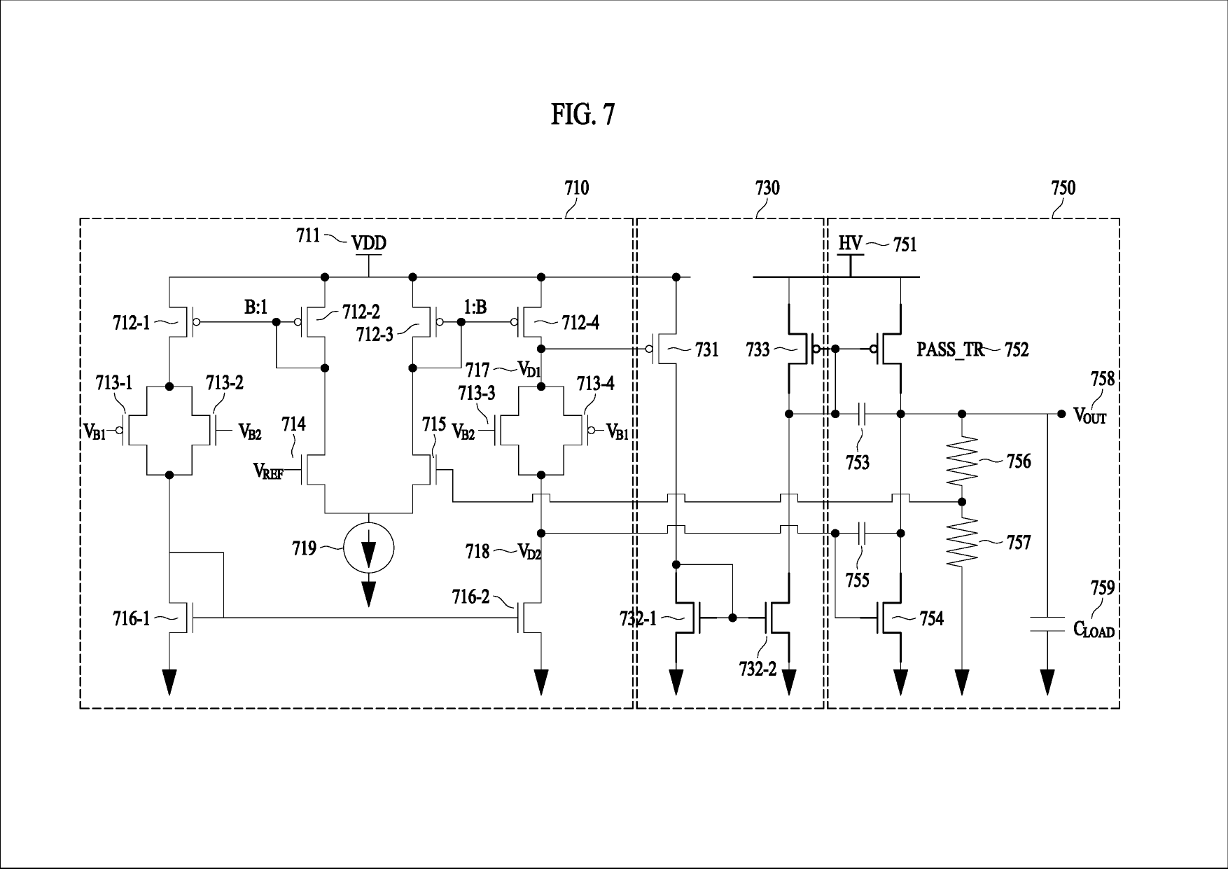

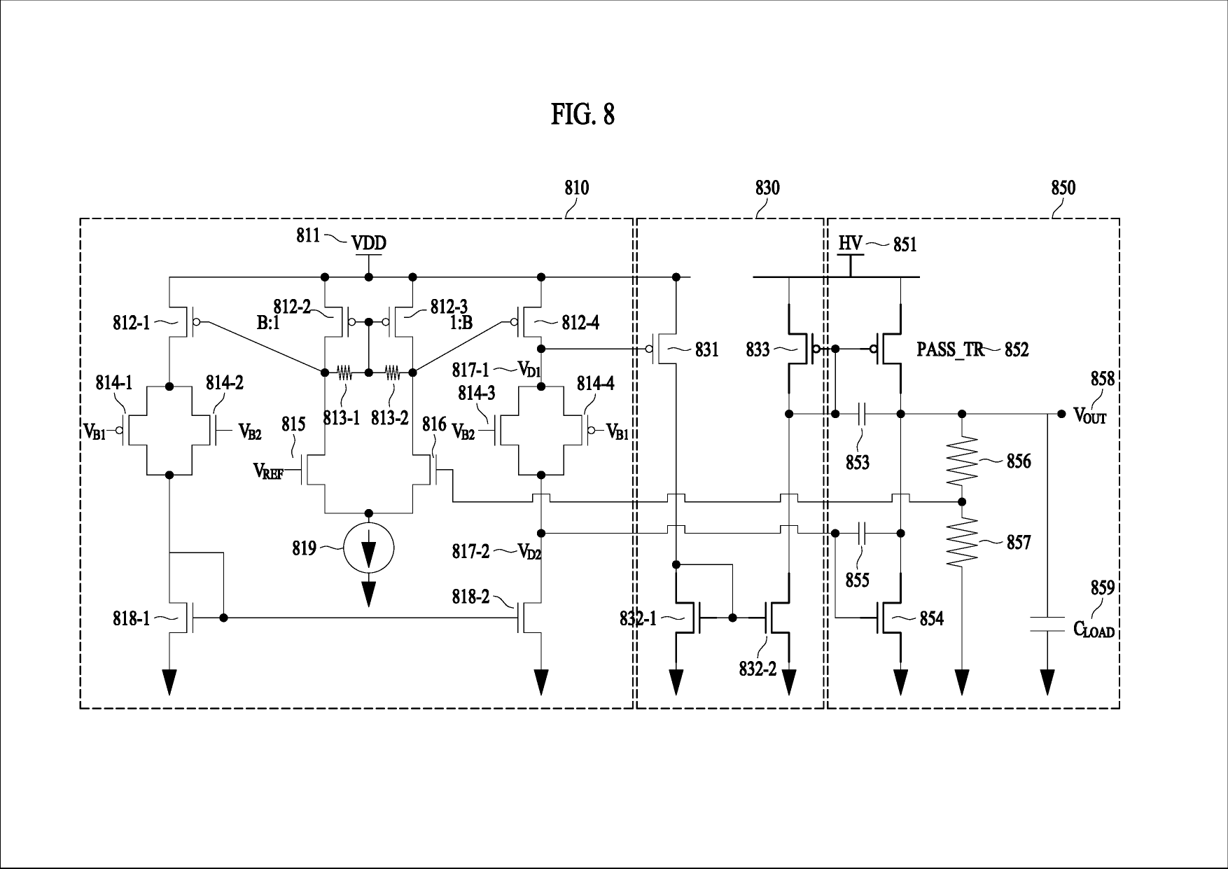

A detailed example of the symmetrical CMOS OTA circuit or the symmetrical CMOS OTA circuit including the resistive common feedback circuit will be described with reference to FIGS. 7 and 8.

In an example embodiment, the voltage conversion circuit 130 may include a plurality of transistors and perform voltage conversion by controlling and operating the OTA circuit 110 and controlling and operating the plurality of transistors with a high voltage value of the input voltage.

In an example embodiment, the voltage conversion circuit 130 may include connection of a transistor to which the high voltage among the heterogeneous voltages is applied. The transistor may be connected to the ground to form one high-voltage current path.

In an example embodiment, the voltage conversion circuit 130 may include a first PMOS transistor in which the first current which is the output current of the OTA circuit 110 is applied to a gate thereof and a second PMOS transistor in which the input voltage which is the high voltage is applied to a source thereof and may be a circuit in which the power source voltage is electrically connected to a source of the first PMOS transistor and a first output voltage is output to a drain of the second PMOS transistor.

In an example embodiment, the voltage conversion circuit 130 may further include a current mirror circuit.

For example, the current mirror circuit may include a first transistor and a second transistor. A drain of the first transistor and a gate of the first transistor may be electrically connected. The drain of the first transistor and a gate of the second transistor may be electrically connected. Accordingly, a current flowing in the first transistor may set a gate-source voltage, so that a current identical to the current flowing in the first transistor may flow also in the second transistor.

The current mirror circuit may represent a circuit that duplicates a current flowing in one transistor so that the duplicated current is in another transistor by using two or more transistors. In the current mirror circuit, the first transistor may receive an input of a current, and the current may be duplicated to be in the second transistor. Since the current which flows in the first transistor may set the gate-source voltage, and since two transistors share a gate, the second transistor may have the equal gate-source voltage. The gate-source voltage may allow the second transistor to have a current identical to that of the first transistor.

In an example embodiment, the voltage output circuit 150 may include the class AB output stage. In addition, the voltage output circuit 150 may include a pass transistor, a load capacitor, and two voltage distribution resistors that distribute the final output voltage.

In an example embodiment, the voltage output circuit 150 may include a push transistor that is electrically connected to a gate of the second PMOS transistor of the voltage conversion circuit 130 by a common gate, in which the first output voltage of the voltage conversion circuit 130 is input to the gate, and in which the input voltage being applied to a source thereof, and the pull-down transistor in which the second current that is the output current of the OTA circuit 110 is input to a gate thereof. Also, a drain of the push transistor and a drain of the pull-down transistor may be electrically connected, so that the voltage output circuit 150 may control the final output voltage with the drain of the pull-down transistor.

The pull-down transistor may be controlled by a current of the floating current source, which is output by the low voltage among the heterogeneous voltages, which are the input voltage, and the push transistor may be controlled by the high voltage among the heterogeneous voltages.

In an example embodiment, a Miller capacitor may be connected between a final voltage output of the voltage output circuit 150 and a gate of the push transistor, and the Miller capacitor may be connected between the final voltage output of the voltage output circuit 140 and a gate of the pull-down transistor.

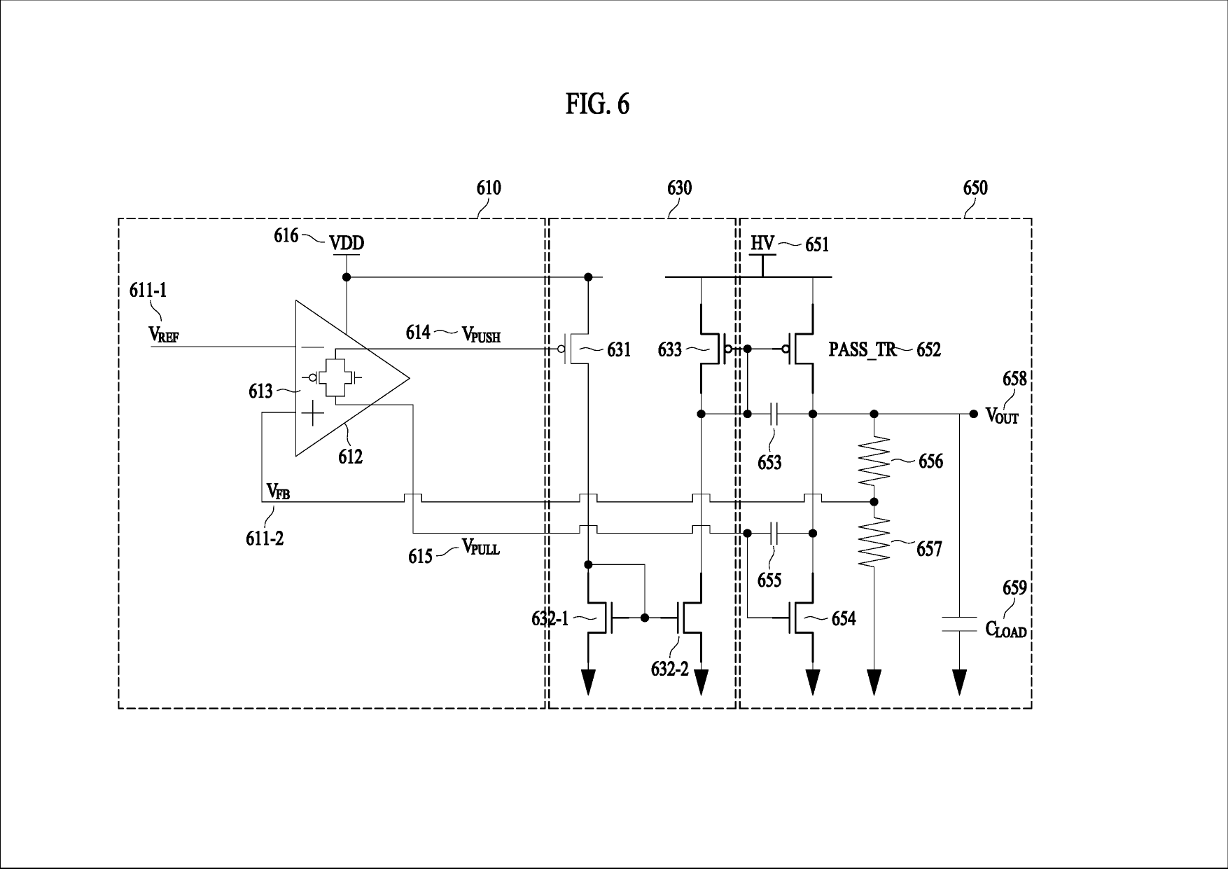

Hereinafter, a detailed example of the voltage control circuit including the floating current source which takes the heterogeneous voltages as the input will be described with reference to FIGS. 6 through 8.

FIG. 6 illustrates a voltage control circuit having heterogeneous input voltages according to an example embodiment.

Referring to FIG. 6, the voltage control circuit 100 may include an operation transconductance amplifier (OTA) circuit 610, a voltage conversion circuit 630, and a voltage output circuit 650. The OTA circuit 610, the voltage conversion circuit 630, and the voltage output circuit 650 may be merely an example and include an additional structure or element.

In an example embodiment, the OTA circuit 610 may include an OTA 612 including a Monticelli cell 613 that is one of floating current sources. Depending on example embodiments, the Monticelli cell 613 may be substituted with an element serving as a floating current source of a current source that may not be connected to a ground or a fixed voltage reference point and may independently operate between two points or nodes. However, it is merely an example.

In an example embodiment, the Monticelli cell 613 may include a current source in the OTA 612 and an element in which sources and drains of a PMOS transistor and a NMOS transistor are connected in parallel.

The OTA 612 may amplify a voltage difference between V_{REF}611-1 that is a reference voltage and V_{FB}611-2 that is a feedback voltage to generate a first current for V_{PUSH}614 that is a push voltage and a second current for V_{PULL}615 that is a pull voltage, which are control signals.

The V_{PUSH}614 may push a current toward a load at high-voltage HV 651 to increase Vₒᵤₜ658 that is a final output voltage. The V_{PUSH}614 may be activated when the voltage difference between the V_{REF}611-1 and the V_{FB}611-2 is a positive value and activated when a value of the Vₒᵤₜ658 is lower than a targeted voltage value. In addition, the V_{PUSH}614, which is an output value of the OTA 612, may be electrically connected to a gate of a first transistor 631 to control the first transistor 631 based on the first current which is output from the OTA 612.

The V_{PULL}615 may be generated for decreasing the Vₒᵤₜ658 and activated when the voltage difference between the V_{REF}611-1 and the V_{FB}611-2 is a negative value. Also, the V_{PULL}615 may be electrically connected to a gate of a fifth transistor 654 that is a pull-down transistor of the voltage output circuit 650 to control the fifth transistor 654 based on the second current which is an output current of the OTA 612.

The Monticelli cell 613 may serve to increase or decrease a voltage while maintaining stability and linearity of the first current and the second current which are output currents.

The OTA 612 may operate by receiving V_{DD}616 that is a low-voltage supply source among two voltages from the regulator 200 of FIG. 1 as a positive-side power source terminal voltage.

In an example embodiment, the voltage conversion circuit 630 may include the first transistor 631, a second transistor 632-1, a third transistor 632-2, and a fourth transistor 633. The voltage conversion circuit 630 may contribute to increasing an output of the Vₒᵤₜ658 and generate a path from the low-voltage V_{DD}616 and the high-voltage HV 651 to the ground.

In an example embodiment, the voltage conversion circuit 630 may further include a current mirror circuit. For example, the voltage conversion circuit 630 may have a gate common to the second transistor 632-1 and the third transistor 632-2 and include the current mirror circuit in which a source of each NMOS transistor is electrically connected to the ground.

The first transistor 631 may be a PMOS transistor and serve to supply a current from the V_{DD}616. The first transistor 631 may be controlled by the first current which is an output of the OTA 612 to control the third transistor 632-2 and adjust the Vₒᵤₜ658.

The second transistor 632-1, which is an NMOS transistor may, form a first path of a low-voltage current which connects the first transistor 631 and the ground from the V_{DD}616. An output value of the first transistor 631 may be input to the gate common to the third transistor 632-2, so that the second transistor 632-1 may be controlled.

The third transistor 632-2, which is an NMOS transistor, may form a second path of a high-voltage current from the HV 651 and the fourth transistor 633 to the ground and may serve, together with the fourth transistor 633, to increase a current capacity at an output and control an output voltage.

Since a path in which the high-voltage current flows to the ground is formed of only one path of the second path, power consumption may be less when compared with a voltage control circuit of FIG. 3 that has three paths, and various actions including economically operating a circuit may be performed because the number of required transistors is reduced.

The voltage output circuit 650 may include a pass transistor 652, a first capacitor 653, a second capacitor 655, the fifth transistor 654, a first resistor 656, a second resistor 657, and a load capacitor 659. In an example embodiment, the voltage output circuit 650 may include a class AB output stage.

The pass transistor 652, which is a PMOS transistor, may be connected to the high-voltage HV 651 and receive a gate signal together with the fourth transistor 633. Also, the pass transistor 652 may serve to switch the HV 651 and may transfer the appropriate Vₒᵤₜ658 to the load by controlling a voltage level.

The fifth transistor 654, which is a PMOS transistor, may be the pull-down transistor and controlled by the second current of the OTA 612. Since the fifth transistor 654 may operate by stably receiving a current from the floating current source as the OTA 612 includes the Monticelli cell 613, the fifth transistor 654 may not be controlled by the HV 651.

In an example embodiment, the first capacitor 653 and the second capacitor 655 may be Miller capacitors that are individually connected between a gate of the pass transistor 652 and a drain of the pass transistor 652 and between the gate of the fifth transistor 654 and a drain of the fifth transistor 654 to serve to suppress a voltage spike and noise.

The first resistor 656 and the second resistor 657 may be electrically connected to the Vₒᵤₜ658 and the V_{FB}611-2, which is the feedback voltage of the OTA 612, to control an operation of the OTA 612 according to distribution of the voltage of the Vₒᵤₜ658.

C_{LOAD}659 which is the load capacitor may be electrically connected to the Vₒᵤₜ658 to serve to maintain overall stability of the circuit and minimize or reduce a voltage change.

As a high-voltage current path from the high-voltage HV 651 to the ground become reduced, the voltage control circuit 100 which includes the OTA circuit 610 including the Monticelli cell 613 and the voltage output circuit 650 including the class AB output stage according to an example embodiment may reduce the power consumption while rapidly receiving a low voltage even in a pull-down situation.

FIG. 7 illustrates a voltage control circuit including a class AB output stage having heterogeneous input voltages and a symmetrical complementary metal-oxide-semiconductor (CMOS) operational transconductance amplifier (OTA).

Referring to FIG. 7, in an example embodiment, the voltage control circuit 100 may include a symmetrical CMOS OTA circuit 710, a voltage conversion circuit 730, and a voltage output circuit 750.

The symmetrical CMOS OTA circuit 710 may generate a high voltage benefit through a symmetrical arrangement of transistors, decrease noise that may occur at an input node, and more stably operate within a broad voltage range.

The symmetrical CMOS OTA circuit 710 illustrated in FIG. 7 is merely an example, and a known symmetrical CMOS circuit for performing a corresponding function may be applied thereto. However, it is merely an example.

A first OTA transistor 712-1, a second OTA transistor 712-2, a third OTA transistor 712-3, and a fourth OTA transistor 712-4 that are NMOS transistors may be electrically connected to V_{DD}711 that is a low voltage among heterogeneous voltages, form a symmetrically configured input operation, and provide a high voltage benefit and a sensitive reaction to an input voltage.

In an example embodiment, the first OTA transistor 712-1, the second OTA transistor 712-2, the third OTA transistor 712-3, and the fourth OTA transistor 712-4 may be cascode transistors. A cascode transistor may serve to transfer and amplify an output current of a differential pair.

A fifth OTA transistor 713-1 that is a PMOS transistor and a sixth OTA transistor 713-2 that is an NMOS transistor may be the differential pair, form a current mirror circuit, and duplicate and adjust a current in an output operation.

In addition, a seventh OTA transistor 713-3 and an eighth OTA transistor 713-4 may be elements of the above-described Monticelli cell and serve as a floating current source.

A ninth OTA transistor 714 and a tenth OTA transistor 715 that are NMOS transistors may serve for switching and amplifying. The ninth OTA transistor 714 may receive an input of V_{REF} that is a reference voltage. The tenth OTA transistor 715 may take a feedback voltage of the voltage output circuit 750 as an input. Through this, a voltage may be amplified by using a voltage difference between the feedback voltage and the V_{REF}.

An eleventh OTA transistor 716-1 and a twelfth OTA transistor 716-2 that are NMOS transistors may be electrically connected to a ground and serve to adjust a voltage and maintain stability by controlling a current flow in the circuit.

In an example embodiment, a direct current source 719 may allow a Monticelli cell in the symmetrical CMOS OTA circuit 710 to provide a stable current. The stable direct current source 719 may be required for accuracy of current duplication by the Monticelli cell in the current mirror circuit.

The voltage conversion circuit 730 may include a first transistor 731 that is a PMOS transistor, a second transistor 732-1 that is an NMOS transistor, a third transistor 732-2 that is an NMOS transistor, and a fourth transistor 733 that is a PMOS transistor. Since an operation of each element included in the voltage conversion circuit 730 may perform an operation and a function identical to the operation of the voltage conversion circuit 630 described above with reference to FIG. 6, a detailed description thereof will be omitted.

The voltage output circuit 750 may include a pass transistor 752 that is a PMOS transistor, a first capacitor 753, a second capacitor 755, a fifth transistor 754 that is an NMOS transistor, a first resistor 756, a second resistor 757, and a load capacitor 759. In an example embodiment, the voltage output circuit 750 may include a class AB output stage. The operation of each element included in the voltage conversion circuit 730 may perform the operation and the function identical to the operation of the voltage conversion circuit 650 described above with reference to FIG. 6. Thus, a detailed description thereof will be omitted.

FIG. 8 illustrates a voltage control circuit including a class AB output stage having heterogeneous input voltages and a symmetrical complementary metal-oxide-semiconductor (CMOS) operational transconductance amplifier (OTA) of a resistive common mode feedback circuit.

Referring to FIG. 8, the voltage control circuit 100 according to an example embodiment may include a symmetrical CMOS OTA circuit 810 including a resistive common mode feedback circuit, a voltage conversion circuit 830, and a voltage output node 850.

Here, the resistive common mode feedback circuit may measure a common mode voltage at an output node of a differential amplifier and adjust a bias at an amplifier input node in order to maintain the common mode voltage. The resistive common mode feedback circuit may include a feedback resistor and may guarantee that the common mode voltage in the circuit is maintained within a linear operation range through sampling performed through the feedback resistor.

The symmetrical CMOS OTA circuit 810 including the resistive common mode feedback circuit according to an example embodiment may include a first OTA transistor 812-1, a second OTA transistor 812-2, a third OTA transistor 812-3, a fourth OTA transistor 812-4, a first OTA resistor 813-1, a second OTA resistor 813-2, a fifth OTA transistor 814-1, a sixth OTA transistor 814-2, a seventh OTA transistor 814-3, an eighth OTA transistor 814-4, a ninth OTA transistor 815, a tenth OTA transistor 816, an eleventh OTA transistor 818-1, a twelfth OTA transistor 818-2, and a direct current source 819.

The first OTA resistor 813-1 and the second OTA resistor 813-2 may be the feedback resistor and serve to measure the common mode voltage, which is an average voltage of a differential amplifier output. A voltage sampled through the first OTA resistor 813-1 and the second OTA resistor 813-2 may be used as the common mode voltage and provide V_{B1} that is a first reference voltage and V_{B2} that is a second reference voltage, which adjust an input voltage of the amplifier.

Since a configuration and functions of the first OTA transistor 812-1, the second OTA transistor 812-2, the third OTA transistor 812-3, the fourth OTA transistor 812-4, the fifth OTA transistor 814-1, the sixth OTA transistor 814-2, the seventh OTA transistor 814-3, the eighth OTA transistor 814-4, the ninth OTA transistor 815, the tenth OTA transistor 816, the eleventh OTA transistor 818-1, the twelfth OTA transistor 818-2, and the direct current source 819 are identical to respective functions of elements included in the symmetrical CMOS OTA circuit 710, detailed descriptions thereof will be omitted.

The voltage conversion circuit 830 may include a first transistor 831, a second transistor 832-1, a third transistor 832-2, and a fourth transistor 833. An operation of each element included in the voltage conversion circuit 830 may perform an operation and a function identical to the operation of the voltage conversion circuit 630 described above with reference to FIG. 6.

The voltage output node 850 may include a pass transistor 852, a first capacitor 853, a second capacitor 855, a fifth transistor 854, a first resistor 856, a second resistor 857, and a load capacitor 859. In an example embodiment, the voltage output node 850 may include the class AB output stage. An operation of each element included in the voltage conversion circuit 830 may perform an operation and a function identical to the operation of the voltage conversion circuit 650 described above with reference to FIG. 6. Thus, a detailed description thereof will be omitted.

The present specification and drawings have been described with respect to the example embodiments of the present disclosure. Although specific terms are used, it is only used in a general sense to easily explain the technical content of the present disclosure and to help the understanding of the invention, and is not intended to limit the scope of the specification. It will be apparent to those skilled in the art that other modifications based on the technical spirit of the present disclosure may be implemented in addition to the embodiments disclosed herein.

The electronic apparatus according to the above-described example embodiments may include a processor, a memory that stores and executes program data, a permanent storage such as a disk drive, a communication port for communicating with an external device, and a user interface device such as a touch panel, a key, and an icon. Methods implemented by software modules or algorithms may be stored in a computer-readable recording medium as computer-readable code or program instructions executable by the processor. Here, the computer-readable recording medium may include a magnetic storage medium (e.g., a read-only memory (ROM), a random-access memory (RAM), a floppy disk, a hard disk, or the like), an optical reading medium (e.g., a CD-ROM or a digital versatile disc (DVD)), or the like. The computer-readable recording medium may be distributed to computer systems connected by a network so that computer-readable code may be stored and executed in a distributed manner. The medium may be read by a computer, stored in the memory, and executed by the processor.

The present example embodiments may be represented by functional blocks and various processing steps. These functional blocks may be implemented by various numbers of hardware and/or software configurations that execute specific functions. For example, the present example embodiments may adopt integrated circuit configurations such as a memory, a processor, a logic circuit, and a look-up table that may execute various functions by control of one or more microprocessors or other control devices. Similarly to that elements may be executed by software programming or software elements, the present example embodiments may be implemented by programming or scripting languages, such as C, C++, Java, and assembler language, including various algorithms implemented by combinations of data structures, processes, routines, or of other programming configurations. Functional aspects may be implemented by algorithms executed by one or more processors. In addition, the present example embodiments may adopt the related art for electronic environment setting, signal processing, and/or data processing, for example. The terms "mechanism", "element", "means", and "configuration" may be widely used and are not limited to mechanical and physical components. These terms may include meaning of a series of routines of software in association with a processor.

The above-described embodiments are merely examples and other embodiments may be implemented within the scope of the following claims.

What is claimed is:

1. A voltage control circuit comprising:
an operational transconductance amplifier (OTA) circuit comprising a floating current source that is configured to receive a power voltage and is further configured to output a first current and a second current based on a difference between input voltage signals;
a voltage conversion circuit comprising a first transistor that is configured to receive the first current and a second transistor that is configured to receive an input voltage, the second transistor being further configured to output a first voltage based on the first transistor being electrically connected to the power voltage; and
a voltage output circuit comprising a third transistor electrically connected to the second transistor by a common input node and a fourth transistor configured to receive the second current,
wherein the third transistor and fourth transistor are, in combination, configured to output a final output voltage based on receipt of the first output voltage at the common input node and receipt of the input voltage at the third transistor.

2. The voltage control circuit of claim 1, wherein the power voltage has a voltage range from 1.5 volts (V) to 2.5 V, and
wherein the input voltage has a voltage of 10 V or more.

3. The voltage control circuit of claim 2, wherein a minimum value of the input voltage and a maximum value of the power voltage differ by 4.7 times or more.

4. The voltage control circuit of claim 1, wherein the OTA circuit further comprises:
an input n-channel metal-oxide-semiconductor (NMOS) transistor or an input p-channel metal-oxide-semiconductor (PMOS) transistor,
wherein the input voltage signal is input to a gate of the input NMOS transistor or a gate of the input PMOS transistor.

5. The voltage control circuit of claim 1, wherein the OTA circuit further comprises:
an input n-channel metal-oxide-semiconductor (NMOS) transistor;
an input p-channel metal-oxide-semiconductor (PMOS) transistor;
a cascode PMOS transistor; and
a cascode NMOS transistor,
wherein a drain of the NMOS transistor is electrically connected to a source of the cascode PMOS transistor,
wherein a drain of the PMOS transistor is electrically connected to a drain of the cascode NMOS transistor,
wherein a source of the cascode NMOS transistor is electrically connected to a ground, and
wherein the source of the cascode PMOS transistor is electrically connected to the power voltage.

6. The voltage control circuit of claim 1, wherein the OTA circuit further comprises:
a differential pair of n-channel metal-oxide-semiconductor (NMOS) transistors or p-channel metal-oxide-semiconductor (PMOS) transistors; and
a current mirror circuit,
wherein each gate of the differential pair is configured to receive an input signal,
wherein sources of the differential pair are electrically connected and are configured to receive a constant bias current, and
wherein drains of the differential pair are electrically connected to the current mirror circuit.

7. The voltage control circuit of claim 6, wherein the OTA circuit further comprises:
a first resistor;
a second resistor; and
a symmetrically structured cascode transistor, and
wherein each of the first resistor and the second resistor is electrically connected between a gate and a drain of the cascode transistor and configured to sense a common mode voltage.

8. The voltage control circuit of claim 1, wherein a Miller capacitor is electrically connected between the final output voltage of the voltage output circuit and a gate of the third transistor, and
wherein a Miller capacitor is electrically connected between the final output voltage of the voltage output circuit and a gate of the fourth transistor.

9. The voltage control circuit of claim 1, wherein the voltage conversion circuit further comprises:
a first n-channel metal-oxide-semiconductor (NMOS) transistor; and
a second NMOS transistor,
wherein a drain of the first NMOS transistor is electrically connected to a gate of the first NMOS transistor,
wherein the gate of the first NMOS transistor is electrically connected to a gate of the second NMOS transistor,
wherein a drain of the first transistor is electrically connected to the drain of the first NMOS transistor, and
wherein a drain of the second transistor is electrically connected to a drain of the second NMOS transistor.

10. The voltage control circuit of claim 9, wherein the voltage conversion circuit further comprises one current path between the input voltage and a ground to which the second transistor, the second NMOS transistor, and a source of the second NMOS transistor are electrically connected.

11. A voltage supply system comprising:
a regulator;
a voltage control circuit configured to receive a regulator voltage from the regulator; and
a generator configured to generate a generator voltage based on a final output voltage generated by the voltage control circuit,
wherein the voltage control circuit comprises:
an operational transconductance amplifier (OTA) circuit comprising a floating current source that is configured to receive a power voltage and is further configured to output a first current and a second current based on a difference between input voltage signals;
a voltage conversion circuit comprising a first transistor configured to receive the first current and a second transistor configured to receive an input voltage, the second transistor being configured to output a first output voltage based on the first transistor being electrically connected to the power voltage; and
a voltage output circuit comprising a third transistor electrically connected to the second transistor by a common input node and a fourth transistor configured to receive the second current,
wherein the third transistor and the fourth transistor are, in combination, configured to output the final output voltage based on receipt of the first output voltage at the common input node and receipt of the input voltage at the third transistor.

12. The voltage supply system of claim 11, wherein the power voltage has a voltage range from 1.5 volts (V) to 2.5 V, and
wherein the input voltage has a voltage of 10 V or more.

13. The voltage supply system of claim 12, wherein a minimum value of the input voltage and a maximum value of the power voltage differ by 4.7 times or more.

14. The voltage supply system of claim 11, wherein the OTA circuit further comprises:
an input n-channel metal-oxide-semiconductor (NMOS) transistor or an input p-channel metal-oxide-semiconductor (PMOS) transistor,
wherein the input voltage signal is input to a gate of the input NMOS transistor or a gate of the input PMOS transistor.

15. The voltage supply system of claim 11, wherein the OTA circuit further comprises:
an input n-channel metal-oxide-semiconductor (NMOS) transistor;
an input p-channel metal-oxide-semiconductor (PMOS) transistor;
a cascode PMOS transistor; and
a cascode NMOS transistor,
wherein a drain of the NMOS transistor is electrically connected to a source of the cascode PMOS transistor,
wherein a drain of the PMOS transistor is electrically connected to a drain of the cascode NMOS transistor,
wherein a source of the cascode NMOS transistor is electrically connected to a ground, and
wherein the source of the cascode PMOS transistor is electrically connected to the power voltage.

16. The voltage supply system of claim 11, wherein the OTA circuit further comprises:
a differential pair of n-channel metal-oxide-semiconductor (NMOS) transistors or p-channel metal-oxide-semiconductor (PMOS) transistors; and
a current mirror circuit,
wherein each gate of the differential pair is configured to receive an input signal,
wherein sources of the differential pair are electrically connected and are configured to receive a constant bias current, and
wherein drains of the differential pair are electrically connected to the current mirror circuit.

17. The voltage supply system of claim 16, wherein the OTA circuit further comprises:
a first resistor;
a second resistor; and
a symmetrically structured cascode transistor, and
wherein each of the first resistor and the second resistor is electrically connected between a gate and a drain of the cascode transistor and configured to sense a common mode voltage.

18. The voltage supply system of claim 11, wherein a Miller capacitor is electrically connected between the final output voltage of the voltage output circuit and a gate of the third transistor, and
wherein a Miller capacitor is electrically connected between the final output voltage of the voltage output circuit and a gate of the fourth transistor.

19. The voltage supply system of claim 11, wherein the voltage conversion circuit further comprises:
wherein a first n-channel metal-oxide-semiconductor (NMOS) transistor; and
wherein a second NMOS transistor,
wherein a drain of the first NMOS transistor is electrically connected to a gate of the first NMOS transistor,
wherein the gate of the first NMOS transistor is electrically connected to a gate of the second NMOS transistor,
a drain of the first transistor is electrically connected to the drain of the first NMOS transistor, and
a drain of the second transistor is electrically connected to a drain of the second NMOS transistor.

20. The voltage supply system of claim 19, wherein the voltage conversion circuit further comprises one current path between the input voltage and a ground to which the second transistor, the second NMOS transistor, and a source of the second NMOS transistor are electrically connected.
